(19) United States
(12) Patent Application Publication
(10) Pub. No.: US 2002/0179006 A1
(43) Pub. Date: Dec. 5, 2002

(54) Method for the preparation of a semiconductor substrate with a non-uniform distribution of stabilized oxygen precipitates

(75) Inventors: Marco Borgini, Borgo Vercelli (IT); Daniela Gambaro, Galliate (IT); Marco Ravani, Novara (IT); Michael J. Ries, St. Charles, MO (US); Laura Sacchetti, Milano (IT); Robert W. Standley, Chesterfield, MO (US); Robert J. Falster, London (GB); Mark G. Stinson, East Alton, IL (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/127,509

(22) Filed: Apr. 22, 2002

Related U.S. Application Data
(60) Provisional application No. 60/285,180, filed on Apr. 20, 2001.
(60) Provisional application No. 60/345,165, filed on Dec. 21, 2001.

(51) Int. Cl. C30B 25/00; C30B 23/00; C30B 28/12; C30B 28/14; H01L 21/302; H01L 21/461

(52) U.S. Cl. 117/95; 117/84; 438/689

(57) ABSTRACT

The process relates to a process for nucleating and growing oxygen precipitates in a silicon wafer. The process includes subjecting a wafer having a non-uniform concentration of crystal lattice vacancies with the concentration of vacancies in the bulk layer being greater than the concentration of vacancies in the surface layer to a non-isothermal heat treatment to form of a denuded zone in the surface layer and to cause the formation and stabilization of oxygen precipitates having an effective radial size 0.5 nm to 30 nm in the bulk layer. The process optionally includes subjecting the stabilized wafer to a high temperature thermal process (e.g. epitaxial deposition, rapid thermal oxidation, rapid thermal nitridation and etc.) at temperatures in the range of 1000° C. to 1275° C. without causing the dissolution of the stabilized oxygen precipitates.

### REFERENCE TO RELATED APPLICATIONS

This application claims priority from U.S. provisional application Serial No. 60/285,180, filed on Apr. 20, 2001, and U.S. provisional application Serial No. 60/345,165, filed Dec. 21, 2001, the entire disclosures which are incorporated herein by reference.

### BACKGROUND OF THE INVENTION

The present invention generally relates to the preparation of a semiconductor substrate having a non-uniform depth distribution of stabilized oxygen precipitates capable of surviving high temperature thermal processes. More precisely, the present invention relates to a process for producing single-crystal silicon wafers wherein the single-crystal silicon wafer is rapid thermally annealed to cause the formation of a non-uniform depth distribution of crystal lattice vacancies, then subjected to an oxygen precipitation heat treatment to form an oxygen precipitate concentration according to the vacancy distribution, and finally, thermally treated to stabilize the oxygen precipitates. The process of the present invention further relates to such a process wherein an epitaxial layer is subsequently deposited on the surface of the stabilized wafer.

Single-crystal silicon, which is the starting material for most processes for the fabrication of semiconductor electronic components, is commonly prepared with the so-called Czochralski process wherein a single seed crystal is immersed into molten silicon and then grown by slow extraction. As molten silicon is contained in a quartz crucible, it is contaminated with various impurities, among which is mainly oxygen. At the temperature of the silicon molten mass, oxygen comes into the crystal lattice until it reaches a concentration determined by the solubility of oxygen in silicon at the temperature of the molten mass and by the actual segregation coefficient of oxygen in solidified silicon. Such concentrations are greater than the solubility of oxygen in solid silicon at the temperatures typical for the processes for the fabrication of electronic devices. As the crystal grows from the molten mass and cools, therefore, the solubility of oxygen in it decreases rapidly, whereby in the resulting slices or wafers, oxygen is present in supersaturated concentrations.

Thermal treatment cycles which are typically employed in the fabrication of electronic devices can cause the precipitation of oxygen in silicon wafers which are supersaturated in oxygen. Depending upon their location in the wafer, the precipitates can be harmful or beneficial. Oxygen precipitates located in the active device region of the wafer can impair the operation of the device. Oxygen precipitates located in the bulk of the wafer, however, are capable of trapping undesired metal impurities that may come into contact with the wafer. The use of oxygen precipitates located in the bulk of the wafer to trap metals is commonly referred to as internal or intrinsic gettering (“IG”).

Historically, electronic device fabrication processes included a series of steps which were designed to produce silicon having a zone or region near the surface of the wafer which is free of oxygen precipitates (commonly referred to as a “denuded zone” or a “precipitate free zone”) with the balance of the wafer, i.e., the wafer bulk, containing a sufficient number of oxygen precipitates for IG purposes. Denuded zones can be formed, for example, in a high-low-high thermal sequence such as (a) an isothermal heat treatment at a high temperature (>1100° C.) in an inert ambient for a period of at least about 4 hours, to dissolve oxygen precipitate nuclei formed during crystal growth and out-diffuse oxygen from the near-surface regions, (b) an isothermal heat treatment at a low temperature (600-750° C.) to cause oxygen precipitate nuclei to form and (c) isothermal growth of oxygen (SiO₂) precipitates at a high temperature (1000-1150° C.) to a size sufficient to survive later high temperature processes in device manufacture, and ultimately, to a size large enough to getter metallic contaminants. See, e.g., F. Shimura, Semiconductor Silicon Crystal Technology, Academic Press, Inc., San Diego Calif. (1989) at pages 361-367 and the references cited therein.

More recently, however, advanced electronic device manufacturing processes such as DRAM manufacturing processes have begun to minimize the use of high temperature process steps. Although some of these processes retain enough of the high temperature process steps to produce a denuded zone and sufficient density of bulk precipitates, the tolerances on the material are too tight to render it a commercially viable product. Other advanced electronic device manufacturers utilize rapid thermal anneal processes for dopant activation or to deposit a nitride or oxide layer on the surface of a silicon substrate, e.g. a rapid thermal oxidation (RTO) and/or rapid thermal nitridation (RTN). Such rapid thermal processes typically subject the substrate to high temperatures, i.e., as high as 1000° C., 1050° C. and even 1100° C. or greater, for relatively short periods of time. Such processes typically dissolve pre-existing oxygen precipitate nuclei, much like the initial high step of the “high-low-high” sequence described above, but do not result in any significant oxygen out-diffusion of oxygen atoms. Although the wafers subjected to the RTO and/or RTN processes may by be substantially free of oxygen precipitates in the device region, the wafers will also be substantially free of oxygen precipitates in the wafer bulk and therefore not enjoy the benefits of intrinsic gettering.

Still other advanced electronic device manufacturing processes contain no high temperature thermal treatment at all and as such will not dissolve pre-existing oxygen precipitates or form a desired oxygen precipitate profile wherein the oxygen precipitates are formed in the bulk region but not in the device region. Because of the problems associated with oxygen precipitates in the active device region, therefore, these electronic device fabricators must use silicon wafers which are incapable of forming oxygen precipitates anywhere in the wafer under their process conditions.

Alternatively, some advanced electronic device manufacturing processes use silicon wafers having an epitaxial layer deposited on the surface. Advantageously, the epitaxial layer typically does not have a significant concentration of interstitial oxygen atoms and therefore does not form oxygen precipitates in the epitaxial layer during typical device manufacturing processes. However, epitaxial deposition processes utilize high temperatures, much like the RTO or RTN process and typically result in the dissolution of pre-existing oxygen precipitate nuclei formed during the crystal growth process. Thus, epitaxial wafers frequently do not have oxygen precipitates in the wafer bulk or form oxygen precipitates in modern device manufacturing processes and as such do not enjoy the benefits of intrinsic gettering.

One solution has been proposed in Japanese Patent Application No. 8-24796, Asayama et al. which discloses: (a) baking silicon wafers at 1150° C. in a H₂ atmosphere; (b) depositing epitaxial layers onto the surfaces of the wafers at temperatures of 1100,1150, and 1200° C.; and (c) cooling the wafers at rates of 5, 10, and 15° C./sec to cause oxygen precipitate nuclei to form in the substrate. According to Asayama et al., the process produces epitaxial wafer having a substrate that contains a supersaturated concentration of oxygen, and an epitaxial layer that contains no oxygen such that subsequent thermal treatments at between 700° C. and 1000° C. performed at the start of a device fabrication process will result in the formation of an intrinsic gettering region and an active device region with excellent crystallinity. However, as stated earlier some advanced device manufacturing processes do not include enough time at high temperatures to grow oxygen precipitates to a size sufficient to getter impurities. Other processes begin with a rapid thermal process that not only fail to grow pre-existing oxygen precipitate nuclei, but may in fact dissolve pre-existing oxygen precipitation nuclei.

### SUMMARY OF THE INVENTION

Among the objects of the invention, therefore, is the provision of a process for producing a single crystal silicon wafer having a non-uniform depth distribution of stabilized oxygen precipitate nuclei capable of surviving high temperature thermal processes; the provision of a process for producing a silicon epitaxial wafer having a non-uniform depth distribution of oxygen precipitate nuclei in the substrate upon which the epitaxial layer is deposited; the provision of such a process wherein the oxygen precipitates rapidly nucleate and stabilize according to a pre-existing non-uniform vacancy distribution; the provision of such a process wherein the oxygen precipitate nuclei are grown and stabilized prior to the deposition of the epitaxial layer so that the oxygen precipitate nuclei survive the epitaxial deposition process; the provision of such a process wherein oxygen precipitates are grown to a size a sufficient to produce IG effects.

Briefly, therefore, the present invention is directed to a process for preparing a single crystal silicon wafer having a non-uniform depth distribution of oxygen precipitate nuclei in the wafer. In the process, a wafer having a non-uniform concentration of crystal lattice vacancies with the concentration of vacancies in the bulk layer being greater than the concentration of vacancies in the surface layer is heated to a nucleation temperature, Tₙ, for a time period, tₙ, of at least about 15 minutes to form oxygen precipitate nuclei in the bulk layer wherein Tₙ is from about 750° C. to about 900° C. to an oxygen diffusion length, Lₙ. The temperature of the wafer is then increased from Tₙ to a growth temperature, T_{g}, over a time period t_{R} of at least about 2 minutes to grow oxygen precipitates at the site of the nuclei wherein T_{g} is at least about 10° C. greater than Tₙ and then cooled to a final temperature, T_{f}, wherein T_{f} is less than about 650° C. to provide a diffusion length L_{R} such that the total diffusion length, Lₜ, is sufficient to produce oxygen precipitates having an effective radius of from about 0.5 nm to about 20 nm. The oxygen precipitation and stabilization process of the present invention requires a significantly shorter total cycle time than would be required to provide an equivalent total diffusion length by heat treating the wafer at the nucleation temperature to provide and equivalent total diffusion length, i.e. to provide a Lₙ=Lₜ.

The process is further directed to a process for nucleating and growing oxygen precipitates in a silicon wafer having a non-uniform concentration of crystal lattice vacancies with the concentration of vacancies in the bulk layer being greater than the concentration of vacancies in the surface layer. The process includes heating the wafer to a temperature, Tₙ, to form oxygen precipitate nuclei in the bulk layer wherein Tₙ is from about 750° C. to about 900° C., increasing the temperature from Tₙ to a temperature, T_{g}, to grow oxygen precipitates at the site of the nuclei wherein Tₙ is at least about 10° C. greater than Tₙ and controlling the rate at which the temperature is increased from Tₙ to T_{g} to provide a population of oxygen precipitates which are stable at a processing temperature, Tₚ wherein Tₚ greater than T_{g}. The wafer is then cooled to a final temperature, T_{f}, wherein T_{f} is less than about 650° C. before the oxygen precipitates grow to a size of 30 nm or greater.

The silicon wafer having a non-uniform concentration of crystal lattice vacancies with the concentration of vacancies in the bulk layer being greater than the concentration of vacancies in the surface layer may be produced prior to the above processes by first subjecting a wafer sliced from an ingot grown by a conventional Czochralski process to a heat-treatment to form crystal lattice vacancies in the front surface and bulk layers, and as part of the heat treatment, the cooling rate of the heat-treated wafer is controlled to produce a wafer having a non-uniform vacancy concentration profile with the concentration in the bulk layer being greater than the concentration in the surface layer.

The present invention is further directed to a process wherein an oxygen precipitate stabilized wafer produced by the above processes is subjected to an epitaxial deposition process to deposit an epitaxial layer on the surface of the wafer. Advantageously, the oxygen precipitates formed and stabilized by the above processes survive the epitaxial deposition process.

Other objects and features of this invention will be, in part, apparent and, in part, pointed out hereinafter.

### BRIEF DESCRIPTION OF THE DRAWINGS

FIG. 1 is a schematic depiction of the ideal precipitation heat treatment process.

FIG. 2 is a graph of the critical radius verses temperature for various interstitial oxygen concentrations.

FIG. 3 is a schematic depiction of the non-isothermal oxygen precipitate nucleation and stabilization heat treatment.

### DETAILED DESCRIPTION OF THE PREFERRED EMBODIMENTS

In accordance with the present invention, a process has been discovered for preparing a silicon wafer having a density of oxygen precipitates which are capable of surviving high temperature processes such as, for example, epitaxial deposition, rapid thermal oxidation or rapid thermal nitridation. Advantageously, this wafer may be prepared in a matter of minutes using tools which are in common use in the semiconductor silicon manufacturing industry. According to the process of the present invention, a single crystal silicon wafer having essentially any oxygen content attainable by the Czochralski growth, is first subjected to an ideal precipitating wafer heat treatment process. This process creates a “template” in the silicon which determines or “prints” the manner in which oxygen will precipitate. The ideal precipitating wafer is then subjected to a thermal anneal to precipitate oxygen and stabilize the oxygen precipitates so that they are capable of surviving the high temperature processes described above. The stabilized wafer may be used directly in device manufacturing processes which do not include thermal conditions necessary to form oxygen precipitates with a desired size or concentration and/or concentration profile. In another embodiment, the wafer is subjected to a high temperature process such as, for example, epitaxial deposition, rapid thermal oxidation or rapid thermal nitridation. Typically the wafer may be used as a substrate upon which an epitaxial layer is deposited. According to the process of the present invention, the oxygen precipitates may be grown to a size sufficient to getter metal contaminants from the surface region of the wafer, or alternatively, may be grown to an intermediate size such that they are capable of surviving high temperature processes and such that the precipitates continue to grow during the device manufacturing process, eventually achieving a size sufficient to getter metal contaminants from the surface region of the wafer.

A. Ideal Precipitating Wafer Process

The starting material for the wafer of the present invention is a silicon wafer which has been sliced from a single crystal ingot grown in accordance with conventional Czochralski (“CZ”) crystal growing methods, typically having a diameter of about 150 mm, 200 mm, 300 mm or more. The wafer may be polished or, alternatively, lapped and etched but not polished. Such methods, as well as standard silicon slicing, lapping, etching, and polishing techniques are disclosed, for example, in F. Shimura, Semiconductor Silicon Crystal Technology, Academic Press, 1989, and Silicon Chemical Etching, (J. Grabmaier ed.) Springer-Verlag, New York, 1982 (incorporated herein by reference). In one embodiment, the wafers are polished and cleaned by standard methods known to those skilled in the art. See, for example, W. C. O'Mara et al., Handbook of Semiconductor Silicon Technology, Noyes Publications.

In general, the starting wafer may have an oxygen concentration falling anywhere within the range attainable by the CZ process, which is typically about 5×10¹⁷ to about 9×10¹⁷ atoms/cm³ or about 10 to about 18 PPMA (e.g., about 10 to about 12 or 15 ppma, as determined in accordance with ASTM calibration; Oᵢ=4.9α, where α is the absorption coefficient of the 1107 cm⁻¹ absorption band; new ASTM standard F-121-83). In addition, the starting wafer preferably has an absence of stabilized oxygen precipitates (i.e., oxygen precipitates which cannot be dissolved or annealed out of the wafer at a temperature of about 1200° C. or less) in the near-surface region of the wafer.

Substitutional carbon, when present as an impurity in single crystal silicon, has the ability to catalyze the formation of oxygen precipitate nucleation centers. For this and other reasons, therefore, it is preferred that the single crystal silicon starting material have a low concentration of carbon. That is, the single crystal silicon should have a concentration of carbon which is less than about 5×10¹⁶ atoms/cm³, preferably which is less than 1×10¹⁶ atoms/cm³, and more preferably less than 5×10¹⁵ atoms/cm³.

In general, a rapid thermal treatment is carried out to form a distribution of crystal lattice vacancies which establish a template for oxygen precipitation in the wafer. In one embodiment, the template is for a wafer having oxygen precipitates in the wafer bulk but a low density of, and preferably an essential absence of, oxygen precipitates in a near-surface region; advantageously, denuded zones of any desired depth may be obtained. For example, denuded zone depths of 70 micrometers, 50 micrometers, 30 micrometers, 20 micrometers, or even 10 micrometers or less may be reliably and reproducibly obtained.

The use of a rapid thermal process to form a distribution of crystal lattice vacancies which, in turn, establish a template for oxygen precipitation, is generally described in Falster et al., U.S. Pat. Nos. 5,994,761, 6,191,010 and 6,180,220, all of which are incorporated herein by reference in their entirety. The “ideal precipitating process” described therein typically yields a non-uniform distribution of crystal lattice vacancies, with the concentration in the wafer bulk being higher than in a surface layer. Upon a subsequent, oxygen precipitation heat treatment, the high concentration of vacancies in the wafer bulk form oxygen precipitate nucleation centers, which aid in the formation and growth of oxygen precipitates; the concentration of vacancies in the near-surface region is insufficient for such oxygen precipitate nucleation centers to form. As a result, a denuded zone forms in the near-surface region and oxygen precipitates, sometimes referred to as bulk microdefects or simply BMDs, form in the wafer bulk. As described therein, denuded zones of a depth in the range of 50 to 100 microns may reliably be formed.

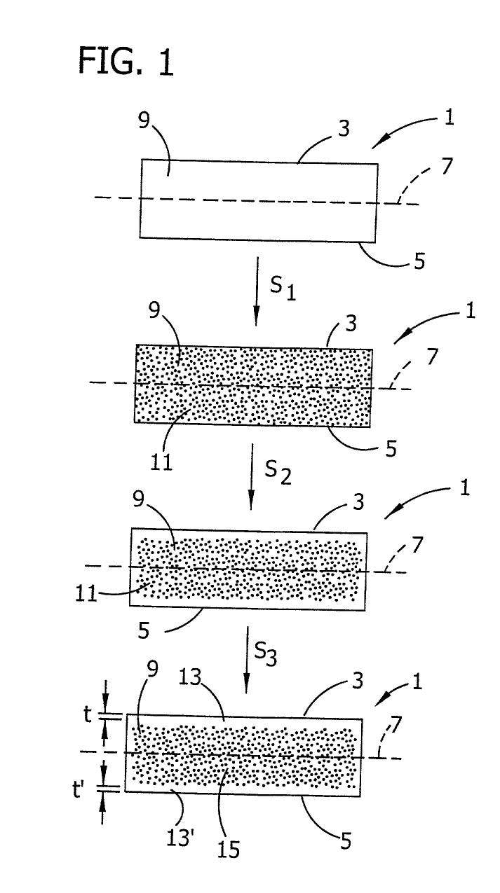

Referring now to FIG. 1, the starting material for the present process is a single crystal silicon wafer 1, having a front surface 3, a back surface 5, an imaginary central plane 7 between the front and back surfaces, and a wafer bulk 9 comprising the wafer volume between the front and back surfaces. The terms “front” and “back” in this context are used to distinguish the two major, generally planar surfaces of the wafer; the front surface of the wafer as that term is used herein is not necessarily the surface onto which an electronic device will subsequently be fabricated nor is the back surface of the wafer, as that term is used herein, necessarily the major surface of the wafer which is opposite the surface onto which the electronic device is fabricated. In addition, because silicon wafers typically have some total thickness variation, warp and bow, the midpoint between every point on the front surface and every point on the back surface may not precisely fall within a plane; as a practical matter, however, the TTV, warp and bow are typically so slight that to a close approximation the midpoints can be said to fall within an imaginary central plane which is approximately equidistant between the front and back surfaces.

In general, in step S₁ of the process, the silicon wafer 1 is subjected to a heat-treatment step in which the wafer is heated to an elevated temperature to form and thereby increase the number density of crystal lattice vacancies 11 in wafer 1. Preferably, this heat-treatment step is carried out in a rapid thermal annealer in which the wafer is rapidly heated to a target temperature and annealed at that temperature for a relatively short period of time. In general, the wafer is subjected to a temperature in excess of 1175° C., typically at least about 1200° C. and, in one embodiment, between about 1200° C. and 1300° C. The wafer will generally be maintained at this temperature for at least one second, typically for at least several seconds (e.g., at least 3, 5, etc.) or even several tens of seconds (e.g., at least 20, 30, 40, etc.) and, depending upon the desired characteristics of the wafer and the atmosphere in which the wafer is being annealed, for a period which may range up to about 60 seconds (which is near the limit for commercially available rapid thermal annealers).

Upon completion of the rapid thermal annealing step, the wafer, in step S₂, is rapidly cooled through the range of temperatures at which crystal lattice vacancies are relatively mobile in the single crystal silicon, vacancies typically being mobile in silicon within a commercially practical period of time down to temperature in excess of about 700° C., 800° C., 900° C. or even 1000° C. As the temperature of the wafer is decreased through this range of temperatures, some vacancies recombine with silicon self-interstitial atoms and others diffuse to the front surface 3 and back surface 5, thus leading to a change in the vacancy concentration profile with the extent of change depending upon the length of time the wafer is maintained at a temperature within this range. If the wafer were slowly cooled, the vacancy concentration would once again become substantially uniform throughout wafer bulk 9 with the concentration being an equilibrium value which is substantially less than the concentration of crystal lattice vacancies immediately upon completion of the heat treatment step.

However, as further described herein, by rapidly cooling the wafer, either alone or in conjunction with control of the ambient in which the wafer is heat-treated and cooled, a non-uniform distribution of crystal lattice vacancies can be achieved, the concentration in the wafer bulk being greater than the concentration in a region near the surface. For example, process conditions (e.g., cooling rate) may be controlled, for example, such that the maximum vacancy concentration is a distance of at least about 20 micrometers, 30 micrometers, 40 micrometers, 50 micrometers or more from the wafer surface. In one embodiment, the maximum vacancy concentration is at or near a central plane 7, the vacancy concentration generally decreasing in the direction of the front surface 3 and back surface 5 of the wafer. In a second embodiment, the maximum vacancy concentration is between the central plane 7 and a layer or region near the surface 3 and/or 5 of the wafer (as further described herein), the concentration generally decreasing in the direction of both the surface and the central plane.

In general, the average cooling rate within the range of temperatures in which vacancies are mobile is at least about 5° C. per second, while in some embodiments the rate is preferably at least about 20° C. per second, 50° C. per second, 100° C. per second or more, with cooling rates in the range of about 100° C. to about 200° C. per being particularly preferred in some instances. In this regard it is to be noted that, once the wafer is cooled to a temperature outside the range of temperatures at which crystal lattice vacancies are relatively mobile in the single crystal silicon, the cooling rate does not appear to significantly influence the precipitating characteristics of the wafer and thus does not appear to be narrowly critical.

The rapid thermal annealing and cooling steps may be carried out in, for example, any of a number of commercially available rapid thermal annealing (“RTA”) furnaces in which wafers are individually heated by banks of high power lamps. RTA furnaces are capable of rapidly heating a silicon wafer, for example, from room temperature to about 1200° C. in a few seconds. Additionally, as further described herein below, they may be used to anneal and cool the wafer in a number of different ambients or atmospheres, including those containing oxygen (e.g., elemental oxygen gas, pyrogenic steam, etc.), nitrogen (e.g., elemental nitrogen gas or a nitrogen-contain compound gas such as ammonia), a non-oxygen, non-nitrogen containing gas (e.g., an inert gas like helium or argon), or a mixture or combination thereof.

After subjecting the wafer to the oxygen precipitate nucleation and stabilization heat treatment of the present invention, (further described herein) which causes oxygen precipitates to form according to the vacancy profile, the resulting depth distribution of oxygen precipitates in the wafer is characterized by clear regions of oxygen precipitate-free material (precipitate free zones or “denuded zones”) 13 and 13′ extending from the front surface 3 and back surface 5 to a depth t, t′ respectively. Between these oxygen precipitate-free regions, is a precipitation zone 15 containing, for example, (i) in a first embodiment (which corresponds to the first embodiment of the vacancy concentration profile described above) a substantially uniform density of oxygen precipitates in the wafer bulk, or (ii) in a second embodiment (which corresponds to the second embodiment of the vacancy concentration profile described above) an oxygen precipitate profile wherein the maximum density is between a surface layer and the central plane. In general, the density of precipitates will be greater than about 10⁸ and less than about 10¹¹ precipitates/cm³, with precipitate densities of about 5×10⁹ or 5×10¹⁰ being typical in some embodiments.

The depth t, t′ from the front and back surfaces, respectively, of oxygen precipitate-free material (denuded) zones 13 and 13′ is, in part, a function of the cooling rate through the temperature range at which crystal lattice vacancies are relatively mobile in silicon. In general, the depth t, t′ decreases with decreasing cooling rates, with denuded zone depths of about 10, 20, 30, 40, 50 microns or more (e.g., 70, 80, 90, 100) being attainable. As a practical matter, however, the cooling rate required to obtain shallow denuded zone depths are somewhat extreme and the thermal shock may create a risk of shattering the wafer. Alternatively, therefore, the thickness of the denuded zone may be controlled by selection of the ambient in which the wafer is annealed while allowing the wafer to cool at a less extreme rate. Stated another way, for a given cooling rate, an ambient may be selected which creates a template for a deep denuded zone (e.g., 50+ microns), intermediate denuded zones (e.g., 30-50 microns), shallow denuded zones (e.g., less than about 30 microns), or even no denuded zone. Experience to-date indicates:

1. When a non-nitrogen, non-oxygen-containing gas is used as the atmosphere or ambient in the rapid thermal annealing step and cooling step, the increase in vacancy concentration throughout the wafer is achieved nearly, if not immediately, upon achieving the annealing temperature. The profile of the resulting vacancy concentration (number density) in the cooled wafer is relatively constant from the front of the wafer to the back of the wafer. Maintaining the wafer at an established temperature during the anneal for additional time does not appear, based upon experimental evidence obtained to-date, to lead to an increase in vacancy concentration. Suitable gases include argon, helium, neon, carbon dioxide, and other such inert elemental and compound gasses, or mixtures of such gasses.

2. When a nitrogen-containing atmosphere or ambient is used as the atmosphere in the thermal annealing and cooling steps of the first embodiment, vacancy concentration appears to increase as a function of time at an established annealing temperature. The resulting wafer will have a vacancy concentration (number density) profile which is generally “U-shaped” for a cross-section of the wafer; that is, after cooling, a maximum concentration will occur at or within several micrometers of the front and back surfaces and a relatively constant and lesser concentration will occur throughout the wafer bulk. Hence, the depth of a denuded zone, formed in an oxygen precipitation heat treatment, approaches zero. In addition to nitrogen gas (N₂), nitrogen-containing gases such as ammonia are suitable for use.

3. When the atmosphere or ambient in the rapid thermal annealing and cooling steps contains oxygen, or more specifically when it comprises oxygen gas (O₂) or an oxygen-containing gas (e.g., pyrogenic steam) in combination with a nitrogen-containing gas, an inert gas or both, the vacancy concentration profile in the near surface region is affected. Experimental evidence to date indicates that the vacancy concentration profile of a near-surface region bears an inverse relationship with atmospheric oxygen concentration. Without being bound to any particular theory, it is generally believed that, in sufficient concentration, annealing in oxygen results in the oxidation of the silicon surface and, as a result, acts to create an inward flux of silicon self-interstitials. The flux of silicon interstitials is controlled by the rate of oxidation which, in turn, can be controlled by the partial pressure of oxygen in the ambient. This inward flux of self-interstitials has the effect of gradually altering the vacancy concentration profile by causing recombinations to occur, beginning at the surface and then moving inward, with the rate of inward movement increasing as a function of increasing oxygen partial pressure. When oxygen is used in combination with a nitrogen-containing gas in the ambient during heat-treatment (S₁) and cooling (S₂), an “M-shaped” vacancy profile may be obtained, wherein the maximum or peak vacancy concentration is present in the wafer bulk between the central plane and a surface layer (the concentration generally decreasing in either direction). Such a profile may alternatively be obtained by first heat-treating a wafer in a nitriding or nitrogen-containing ambient and then heat-treating in an oxidizing or oxygen-containing ambient, after cooling the U-shaped profile (as previously described above) becoming M-shaped by the inward flux of interstitials. As a result of the presence of oxygen in the ambient, a region of low vacancy concentration may be created which, following an oxygen precipitation heat treatment, in turn results in the formation of a denuded zone of any arbitrary depth suitable for a particular end use of a device which is to be fabricated from the silicon wafer.

In one embodiment, therefore, the atmosphere during the rapid thermal annealing and cooling steps process typically contains an oxygen partial pressure sufficient to obtain a denuded zone depth of less than about 30 microns, and preferably a denuded zone depth ranging from greater than about 5 microns to less than about 30 microns, from about 10 microns to about 25 microns, or from about 15 microns to about 20 microns. More specifically, the annealing and cooing steps of the present process are typically carried out in an atmosphere comprising (i) a nitrogen-containing gas (e.g., N₂), (ii) a non-oxygen, non-nitrogen containing gas (e.g., argon, helium, etc.), or (iii) a mixture thereof, and (iv) an oxygen-containing gas (e.g., O₂ or pyrogenic steam), the atmosphere having an oxygen partial pressure sufficient to create an inward flux of interstitials (e.g., at least about 1 ppma, 5 ppma, 10 ppma or more) but less than about 500 ppma, preferably less than about 400 ppma, 300 ppma, 200 ppma, 150 ppma or even 100 ppma, and in some embodiments preferably less than about 50, 40, 30, 20 or even 10 ppma. When a mixture of a nitrogen-containing and a non-nitrogen, non-oxygen containing gas is used with the oxidizing gas, the respective ratio of the two (i.e., nitrogen-containing to inert gas) may range from about 1:10 to about 10:1, from about 1:5 to about 5:1, from about 1:4 to about 4:1, from about 1:3 to about 3:1, or from about 1:2 to about 2:1, with ratios of nitrogen-containing gas to inert gas of about 1:5, 1:4, 1:3, 1:2 or 1:1 being preferred in some embodiments. Stated another way, if such a gaseous mixture is used as the atmosphere for the annealing and cooling steps, the concentration of nitrogen-containing gas therein may range from about 1% to less than about 100%, from about 10% to about 90%, from about 20% to about 80% or from about 40% to about 60%.

In this regard it is to be noted that the precise conditions for the annealing and cooling steps may be other than herein described without departing from the scope of the present invention. Furthermore, such conditions may be determined, for example, empirically by adjusting the temperature and duration of the anneal, and the atmospheric conditions (i.e., the composition of the atmosphere, as well as the oxygen partial pressure) in order to optimize the desired depth of t and/or t′.

Regardless of the precise profile, the ideal precipitating wafer can be said to possess a template for oxygen precipitation well-suited for applications requiring a silicon wafer having a denuded zone therein. That is, in high vacancy concentration regions, i.e., the wafer bulk, oxygen clusters rapidly as the wafer is subjected to the oxygen precipitate nucleation and stabilization process described below. In the low vacancy concentration regions, i.e., the near-surface regions, however, the wafer behaves like a normal wafer which lacks pre-existing oxygen precipitate nucleation centers when the wafer is subjected to this oxygen precipitate nucleation and stabilization heat-treatment; that is, oxygen clustering is not observed and a denuded zone is formed. Thus, by dividing the wafer into various zones of vacancy concentration, a template is effectively created through which is written an oxygen precipitate pattern which is fixed the moment the wafer is loaded into the furnace for the oxygen-precipitate nucleation and stabilization heat-treatment.

In this regard, it is to be noted that, while the heat treatments employed in the rapid thermal anneal process may result in the out-diffusion of a small amount of oxygen from the surface of the front and back surfaces of the wafer, the wafer bulk will have a substantially uniform oxygen concentration as a function of depth from the silicon surface. For example, the wafer will have a uniform concentration of oxygen from the center of the wafer to regions of the wafer which are within about 15 micrometers of the silicon surface, more preferably from the center of the silicon to regions of the wafer which are within about 10 micrometers of the silicon surface, even more preferably from the center of the silicon to regions of the wafer which are within about 5 micrometers of the silicon surface and most preferably from the center of the silicon to regions of the wafer which are within 3 micrometers of the silicon surface. In this context, substantially uniform oxygen concentration shall mean a variance in the oxygen concentration of no more than about 50%, preferably no more than about 20% and most preferably no more than about 10%.

In this regard, it is to be further noted that, in general, a denuded zone is a zone occupying the region near the surface of a wafer which has (i) an absence of oxygen precipitates in excess of the current detection limit (currently about 10⁷ oxygen precipitates/cm³) and (ii) a low concentration of, and preferably an essential absence of oxygen precipitation centers which, upon being subjected to an oxygen precipitation heat-treatment, are converted to oxygen precipitates. The presence (or density) of oxygen precipitate nucleation centers cannot be directly measured using presently available techniques. They may be indirectly measured, however, if they are stabilized and oxygen precipitates are grown at these sites by subjecting the silicon to an oxygen precipitation heat treatment. As used herein, therefore, silicon having a low density of oxygen precipitate nucleation centers shall mean silicon which, upon being annealed at a temperature of 800° C. for four hours and then at a temperature of 1000° C. for sixteen hours, has less than about 10⁸ oxygen precipitates/cm³. Similarly, silicon having an essential absence of oxygen precipitate nucleation centers shall mean silicon which, upon being annealed at a temperature of 800° C. for four hours and then at a temperature of 1000° C. for sixteen hours, has less than 10⁷ oxygen precipitates/cm³.

In view of the foregoing, it can be seen that, advantageously, the wafers of the present invention have a template for oxygen precipitation which enables the reliable, reproducible and efficient formation of a denuded zone in a near-surface region of the wafer, and a desirable number of microdefects (oxygen precipitates) in the wafer bulk for internal gettering (e.g., at least about 1×10⁸ cm⁻³) upon being subjected to the oxygen precipitate nucleation and stabilization process described herein.

B. Oxygen Precipitate Nucleation and Stabilization

In general, the oxygen precipitate nucleation and stabilization heat treatment of the present invention causes oxygen precipitates to form according to the vacancy profile in the ideal precipitating wafer. That is, the oxygen precipitates will form in the bulk region, a region having a high concentration of vacancies, and will not form in the surface layer, a region having a low concentration of vacancies. In one embodiment, the oxygen precipitates are stabilized such that they are capable of surviving subsequent high temperature thermal anneals at temperatures not in excess of 1275° C. In another embodiment, the oxygen precipitates in the bulk region grow to a size sufficient to produce intrinsic gettering. The wafer may then be subjected to an epitaxial deposition process to produce an epitaxial wafer. Advantageously, epitaxial deposition processes typically require heating the wafer substrate to a temperature of less than 1275° C. Oxygen precipitates formed and stabilized according to the process of the present invention are capable of surviving typical epitaxial deposition processes.

It should be noted, that although the wafer having stabilized oxygen precipitates is particularly useful as a starting wafer for an epitaxial deposition processes, the wafer may be similarly used as a starting wafer for any high temperature process capable of dissolving non-stabilized oxygen precipitates such as, for example, rapid thermal anneals used for dopant activation, RTO or RTN processes or in any device manufacturing process requiring both a denuded zone and oxygen precipitates in the bulk layer for intrinsic gettering. That is, the present invention provides for a process wherein the oxygen precipitate nucleation and stabilization heat treatment produces oxygen precipitates at a desired concentration and size to produce intrinsic gettering. Alternatively, the process may provide a wafer having oxygen precipitates that are large enough that they are capable of growing to a size sufficient to produce intrinsic gettering in a subsequent device manufacturing process. Stated differently, if the thermal conditions for a particular device manufacturing process are known, the oxygen precipitate nucleation and stabilization heat treatment can be designed to grow the precipitates to an initial size and concentration such that, upon being subjected to all or a portion of the thermal conditions of the device manufacturing process, they grow to a size sufficient to produce intrinsic gettering. Thus, the wafer may be used in any device manufacturing process wherein a wafer having both a denuded zone and intrinsic gettering is desired and is particularly advantageous in device manufacturing processes which are otherwise incapable of forming both a denuded zone and a bulk region containing oxygen precipitates sufficient in size and concentration to produce intrinsic gettering.

The process for precipitating oxygen and growing the precipitates to a critical size sufficient to survive a high temperature process, such as an epitaxial deposition, is mostly limited by the diffusion rate of the oxygen interstitial atoms. In a simple, diffusion limited growth model, the precipitate radius, R, after the wafer is subjected to an isothermal heat treatment for time t at a temperature T is given by:

R=[Wₒₓ×(Cᵢ−C_{i,eq})×D(T)×t]^{1/2} (1)

(Semiconductors and Semimetals, Vol. 42, Oxygen in Silicon, ed. F. Shimura, Academic Press, 1994, p. 367). Wherein, Cᵢ is the initial interstitial oxygen concentration, C_{i,eq} is the equilibrium interstitial oxygen concentration at temperature T, Wₒₓ is the volume of an SiO₂ molecule, D(T) is the diffusivity of interstitial oxygen in Si at temperature T, and t is the heat treatment time at temperature T. Thus for a given interstitial oxygen concentration, the precipitate radius is proportional to the diffusion length, L_{diff.}, such that:

L_{diff.}=(D(T)×t)^{1/2} (2)

wherein, D(T) and t are as defined above. The diffusivity of interstitial oxygen, D(T), is calculated by the equation:

D(T)=(7.8×10⁸μm²/min)(e^{-29,333/T}) (3)

wherein, T is the heat treatment temperature in degrees Kelvin and D(T) has the units μm²/min.

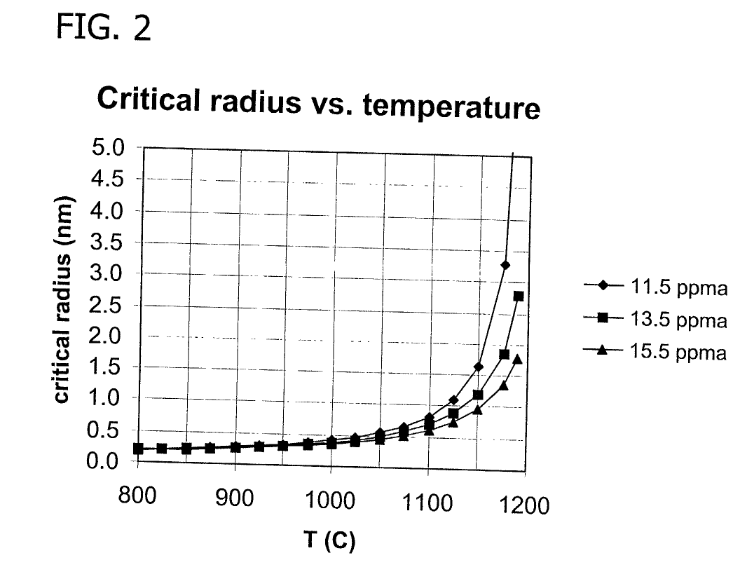

To survive a high temperature process such as an epitaxial deposition, the oxygen precipitate should have a radius, R, greater than a critical radius, R_{c}, which depends on the process temperature to which the wafer will be subjected and wafer interstitial oxygen concentration (Semiconductors and Semimetals, Vol. 42, Oxygen in Silicon, ed. F. Shimura, Academic Press, 1994, pp. 363-367). For example, as shown in FIG. 2, for a given interstitial oxygen concentration and a process temperature ranging from about 800° C. to about 1200° C. there exists a critical radius below which the precipitate may dissolve during the process. Thus, for wafers which may be subjected to a temperature, Tₚ, in a subsequent high temperature process wherein Tₚ is at least about 1000° C., the oxygen precipitates preferably have a radius of at least about 0.5 nm or greater. Wafers which may be subjected to a subsequent high temperature process wherein Tₚ is at least about 1100° C. preferably have a radius of at least about 1 nm or greater. Finally, wafers which may be subjected to a subsequent high temperature process wherein Tₚ is at least about 1150° C. are preferably grown, during the oxygen precipitate nucleation and stabilization process, such that they have a radius of at least about about 1 nm, more preferably at least about 1.5 nm, and most preferably at least about 2 nm or greater depending on the initial oxygen concentration.

In addition, the oxygen precipitates may be grown to a size significantly greater than the critical radius required to stabilize the precipitates and may even be grown to a size sufficient to produce the gettering effect without requiring additional growth during subsequent device manufacturing processes. Oxygen precipitates which provide intrinsic gettering have a radius of preferably at least about 3 nm but may be as large as 5 nm, 10 nm, 20 nm, and even as high as 30 nm or greater. While oxygen precipitates may be grown such that the radius is as high as 30 nm or greater, such precipitates may have a deleterious effect on wafer yield strength. For example, oxygen precipitates with a radius of greater than 30 nm wafers may cause the wafer to be more susceptible to slip dislocations. In addition, the concentration of oxygen precipitates required to provide intrinsic gettering benefits is typically from at least about 10⁷ precipitates/cm³ to about 10¹⁰ precipitates/cm³ or greater with the concentration of the oxygen precipitates typically being inversely proportional to the size of the precipitates such that process conditions which cause the formation of large oxygen precipitates typically results in a smaller precipitate concentration than process conditions which cause the formation of smaller precipitates. Typically, the wafer of present invention has an oxygen precipitate density in the bulk layer of greater than about 1×10⁸ cm³, more typically greater than about 1×9¹⁰ cm⁻³ and sometimes greater than about 1×10¹⁰ cm⁻³. In one embodiment, the wafer of the present invention has an oxygen precipitate density in the range from about 1×10⁸ cm⁻³ to about 1×10¹⁰ cm⁻³ and in another embodiment in the range of from about 1×10⁸ cm⁻³ to about 1×10⁹ cm⁻³. In addition, the wafer of the present invention typically has oxygen precipitates which have a radial size in the range of from about 3 nm to about 30 nm, more typically from about 5 nm to about 15 nm and in one embodiment from 8 nm to about 10 nm to provide intrinsic gettering.

A critical diffusion length, L_{c}, required to form and stabilize the oxygen precipitates may be determined such that for a given oxygen precipitate nucleation and stabilization heat treatment temperature, the time period required to allow the oxygen interstitial atoms to diffuse and combine to form oxygen precipitates and grow to a size sufficient to survive the epitaxial process may be calculated. That is, the critical diffusion length may be determined by the equation:

L_{c}=(D(T)×tₘᵢₙ)^{1/2}=R_{c}/[Wₒₓ×(Cᵢ−C_{i,eq})]^{1/2} (4)

wherein L_{c} is the critical diffusion length in microns, D(T) is the interstitial oxygen diffusivity having the units μm²/min and tₘᵢₙ is the minimum heat treatment time, in minutes, required to grow and stabilize the oxygen precipitates. Thus, from equations (1) through (4), the minimum time, tₘᵢₙ, required to grow and stabilize oxygen precipitates to a size sufficient to survive thermal treatments at a given temperature can be calculated as a function of the oxygen precipitate nucleation and stabilization heat treatment temperature, and the critical diffusion length according to the following equation:

tₘᵢₙ=L_{c}²/[(7.8×10⁸μm²/min)(e^{-29,333}/] (5)

A desired radius may be selected and equations (1) through (4) used to determine the total diffusion length required to produce the desired radius for a given oxygen interstitial concentration. For example, to grow the oxygen precipitates having a radius of about 2.6 nm requires thermal process conditions capable of providing an oxygen diffusion length of about 0.5 μm. Accordingly, ideal precipitating wafers subjected to an oxygen precipitate nucleation and stabilization heat treatment producing a diffusion length of 0.5 μm will form a concentration of oxygen precipitates having a size of about 2.6 nm and thus being capable of surviving an epitaxial deposition process at temperatures not greater than 1275° C.

Oxygen precipitate nucleation and stabilization in an ideal precipitating wafer comprises two stages; a vacancy-enhanced nucleation of small oxygen clusters, followed by their subsequent growth to precipitates large enough to survive subsequent high temperature thermal treatments or even large enough to getter metal impurities.

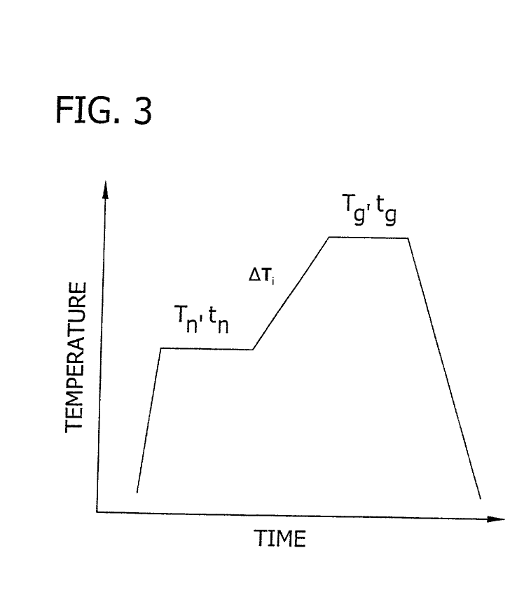

The oxygen precipitate nucleation and stabilization heat treatment of the present invention is a non-isothermal heat treatment as shown schematically in FIG. 3. The non-isothermal heat treatment comprises thermally treating the wafer at a nucleation temperature, Tₙ, falling in the range of from about 750° C. to about 900° C., typically from about 800° C. to about 850° C., and frequently from about 800° C. to about 825° C. The wafer is maintained at the nucleation temperature for a time period, tₙ, which is sufficient to allow oxygen atoms to cluster together to form oxygen precipitate nuclei. In one embodiment, the wafer is maintained at the nucleation temperature for a time period, tₙ, of at least about 15 minutes; in another embodiment, at least about 30 minutes; and in yet another embodiment, at least about 60 minutes. Wafers in some applications may be maintained at the nucleation temperature for a time period, tₙ, of at least about 2 hours or longer.

The temperature of the wafer is then increased or ramped up to a growth temperature, T_{g} over a time period, tᵢ. Typically, T_{g} is at least about 10° C. greater than Tₙ. The rate at which the temperature is ramped up is such that the ramp rate, ΔTᵢ, is sufficiently slow to allow the oxygen precipitate nuclei grow such that the radius of the oxygen precipitate nuclei remain larger than the critical radius. That is, as the temperature is increased, the critical radius increases. If the temperature is increased such that the critical radius is greater than the radius of the oxygen precipitate nuclei, the nuclei will begin to dissolve. Thus, the temperature is increased at a ramp rate, ΔTᵢ, which allows the nuclei to grow such that the radius of the oxygen precipitates is maintained above the critical radius. That is, ΔTᵢ, is controlled such that at each intermediate temperature Tᵢₙₜ. between Tₙ and T_{g}, the radius of the oxygen precipitates remain larger than a critical radius at Tᵢₙₜ, R_{c,Tint}. The temperature may be increased at a ramp rate, ΔTᵢ, of less than about 10° C./min, typically less than about 5° C./min. In one embodiment the temperature is preferably increased at a ramp rate, ΔTᵢ, of from about 1° C./min to about 5° C./min, in another embodiment from about 2° C./min to about 4° C./min and another embodiment from about 3° C./min to about 4° C./min. Thus, to increase the temperature by at least about 10° C. at a rate of less than about 5° C./min, the temperature may be increased from T_{g} to Tₙ. over a period of time, tᵢ, which is typically at least about 2 minutes.

The growth temperature, T_{g}, is typically somewhere in the range of from about 850° C. to about 1150° C., in one embodiment in the range of from about 900° C. to about 1100° C. and in another embodiment in the range of from about 900° C. to about 1000° C. The wafer is maintained at the growth temperature for a time period, t_{g}, required to grow the oxygen precipitates to the desired size. That is, the wafer is typically maintained at the growth temperature for a time period sufficient to ensure the total diffusion length for the oxygen precipitate nucleation and stabilization heat treatment necessary to grow the precipitate to the desired size is achieved.

The duration of the growth stage may vary considerably based on thermal conditions selected for both the nucleation stage and ramp stage and the desired size for the oxygen precipitates. In fact, in cases where the desired radius of the oxygen precipitate nuclei is only slightly in excess of the critical radius, R_{c,g}, at the growth temperature, T_{g}, the wafer may be immediately cooled upon reaching the growth temperature such that t₉ is effectively 0 minutes; whereas, in cases where the desired radius is in excess of the critical radius, i.e., a radius of 3 nm, 5 nm, 10 nm, 20 nm and even as high as 30 nm, the wafer may be maintained at the growth temperature for considerably longer periods of time, i.e. a duration of about 30 minutes, about 1 hour, about 2 hours, about 4 hours and even as long as 8 hours or more.

It should be noted that the oxygen precipitates may continue to grow as the wafer is cooled from T_{g} to a temperature at which the diffusion rate for oxygen interstitial atoms is inconsequential such that the oxygen precipitates do not continue to grow for any commercially practicable time periods. Typically the oxygen precipitates discontinue growing at temperatures less than 700° C., more typically less than 650° C. and still more typically less than 600° C. Accordingly, the wafer may typically be cooled from T_{g} to a final temperature, T_{f}, over a time period t_{d} providing a diffusion length, L_{d}, with T_{f} typically being less than about 700° C., more typically less 650° C. and in one embodiment less than 600° C. While the time period, t_{f}, over which the wafer is cooled from T_{g} to T_{f} is not critical to the present invention, the wafer is typically cooled to T_{f} prior to the to the oxygen precipitates growing to a size greater than 30 nm to avoid the deleterious effects that may be cause by larger precipitates.

The total diffusion length of the non-isothermal oxygen precipitation heat treatment can be determined by calculating the approximate diffusion length for each stage of the heat treatment process and adding each stage in quadrature to obtain the total diffusion length. That is, as discussed above, each step in the process provides some oxygen diffusion length. Stated differently, a diffusion length, Lₙ, caused by the initial isothermal anneal at Tₙ and the diffusion length, L_{g}, caused by the isothermal anneal at T_{g} may be determined using equations (2) and (3). A diffusion length, L_{T}, provided by the temperature increase from Tₙ to T_{g} and a diffusion length, L_{d}, provided by the temperature decrease from T_{g} to T_{f} may be determined using numerical or series expansion methods to integrate equations (2) and (3) over the range of temperatures over which each the ramp occurs. A total diffusion length, L_{T}, provided by the entire process may be calculated by adding Lₙ, Lᵢ, L_{g} and L_{d} in quadrature. Typically, the total diffusion length, L_{T}, is at least about 0.19 μm. In one embodiment, the total diffusion length, L_{T}, is at least about 0.47 μm, in another embodiment at least 0.95 μm and in still another embodiment at least about 1.9 μm. The total cycle time t_{T} necessary to achieve such a diffusion length is the sum of the time necessary to perform each step. That is, the total cycle time may be calculated by adding the time periods tₙ, tᵢ, t_{g} and t_{d}.

As stated earlier, the oxygen precipitate size is limited by the oxygen diffusion length. According to the process of the present invention, therefore, an oxygen precipitate and stabilization process may be designed to provide oxygen precipitates of a desired size by selecting thermal conditions which provide the total diffusion length required to produce the desired size. For example, to grow oxygen precipitates to a radial size of about 2.5 nm in size requires a total diffusion length of about 0.47 μm, which may be provided by isothermally annealing the wafer at a nucleation temperature to provide a diffusion length of about 0.13 μm and then non-isothermally annealing the wafer to provide a diffusion length of about 0.45 μm.

By providing at least a portion of the total oxygen diffusion length using a non-isothermal heat treatment, the total cycle time for the process may be substantially reduced compared to a process wherein the wafer is annealed isothermally at the same temperature of nucleation (e.g. the total cycle time may be reduced by at least 30% and even as much as 50% or greater.) For example, as shown in Table I a non-isothermal oxygen precipitate nucleation and stabilization heat treatment comprising first annealing the wafer at a nucleation temperature of 800° C. for 1 hour, ramping the temperature from about 800° C. to about 900° C. at a rate of about 4° C./minute and then immediately cooling the wafer produced a wafer having a concentration of oxygen precipitation nuclei similar to the isothermal oxygen precipitate nucleation and stabilization heat treatment at a temperature 800° C. for 4 hours with an overall cycle time of about 50% of the isothermal process.

TABLE I
Oxygen Precipitate Concentration formed by both an isothermal anneal
and a non-isothermal anneal isothermal anneal having approximately the
same diffusion length.

| Oxygen precipitate | Oxygen Precipitate | |
|---|---|---|
| nucleation and | Concentration | Total Cycle |
| stabilization Conditions | [Precipitates/cm³] | Time [hr] |
| 800° C. for 4 h | 4.70E+09 | 4.54 |
| 800° C. for 1 h + 4° C./min | 3.84E+09 | 2.29 |
| ramp to 900° C., then | | |
| cool | | |

C. High Temperatured Thermal Process

The oxygen precipitation and stabilization process described above produces a wafer having stabilized oxygen precipitates capable of surviving subsequent high temperature thermal anneals at temperatures not in excess of 1275° C. Accordingly, the wafer may be used as a starting wafer for any high temperature process capable of dissolving non-stabilized oxygen precipitates such as, for example, rapid thermal anneals used for dopant activation, RTO or RTN processes. The wafer having stabilized oxygen precipitates is particularly useful as a starting wafer for an epitaxial deposition processes. Advantageously, epitaxial deposition processes typically require heating a wafer substrate to a temperature greater than the temperature at which non-stabilized oxygen precipitates typically dissolve, but less than 1275° C. Thus, oxygen precipitates formed and stabilized according to the process of the present invention are capable of surviving typical epitaxial deposition processes.

It should be noted, that the epitaxial layer may be deposited onto the entire wafer, or, alternatively, onto only a portion of the wafer. Referring again to FIG. 1, the epitaxial layer preferably is deposited onto the front surface 3 of the wafer 1. In a particularly preferred embodiment, it is deposited onto the entire front surface 3 of the wafer. Whether it is preferred to have an epitaxial layer deposited onto any other portion of the wafer will depend on the intended use of the wafer. For most applications, the existence or non-existence of an epitaxial layer on any other portion of the wafer is not critical.

Single crystal silicon wafers sliced from ingots prepared by the Cz method often have COPs on their surfaces. A wafer used for integrated circuit fabrication, however, generally is required to have a surface which consists essentially of no COPs. A wafer having an essentially COP-free surface may be prepared by depositing an epitaxial silicon layer onto the surface of the wafer. Such an epitaxial layer fills in the COPs and ultimately produces a smooth wafer surface. This has been the topic of recent scientific investigations. See Schmolke et al., The Electrochem. Soc. Proc., vol. PV98-1, p. 855 (1998); Hirofumi et al., Jpn. J. Appi. Phys., vol. 36, p. 2565 (1997). Applicants have discovered in accordance with this invention that COPs on a wafer surface may be eliminated by using an epitaxial silicon layer thickness of at least about 0.1 μm. Typically, the epitaxial layer has a thickness of at least about 0.1 μm and less than about 2 μm. In one embodiment, the epitaxial layer has a thickness of from about 0.25 μm to about 1 μm, and in another embodiment from about 0.65 μm to about 1 μm.

It should be noted that the preferred thickness of the epitaxial layer may vary if the epitaxial layer is used to impart electrical properties to the wafer surface in addition to eliminating COPs. For example, precise control of a dopant concentration profile near the wafer surface may be achieved using an epitaxial layer. Where an epitaxial layer is used for a purpose in addition to eliminating COPs, such a purpose may require an epitaxial layer thickness which is greater than the preferred thickness used to eliminate the COPs. In such an instance, the minimum thickness to achieve the additional desired effect preferably is used. Depositing a thicker layer onto the wafer is generally less commercially desirable because forming the thicker layer requires a greater deposition time and more frequent cleaning of the reaction vessel.

If a wafer has a silicon oxide layer (e.g., a native silicon oxide layer, which forms on a silicon surface when it is exposed to air at room temperature and generally has a thickness of from about 10 to about 15 Å, or an oxide layer deposited as part of the ideal precipitating wafer process) on its surface, the silicon oxide layer preferably is removed from the surface of the wafer before the epitaxial layer is deposited onto the surface. As used herein, the phrase “silicon oxide layer” refers to a layer of silicon atoms which are chemically bound to oxygen atoms. Typically, such a silicon oxide layer contains about 2.0 oxygen atoms per silicon atom.

In a preferred embodiment of this invention, removal of the silicon oxide layer is preferably accomplished by heating the surface of the wafer in an atmosphere consisting essentially of no oxidants (most preferably, the atmosphere is oxidant-free) until the silicon oxide layer is removed from the surface. In a particularly preferred embodiment, the surface of the wafer is heated to a temperature of at least about 1100° C., and more preferably to a temperature of at least about 1150° C. This heating preferably is conducted while exposing the surface of the wafer to an atmosphere comprising a noble gas (e.g., He, Ne, or Ar), H₂, HF, HCl gas, or a combination thereof. More preferably, the atmosphere comprises HF gas, HCl gas, H₂, or a combination thereof; atmospheres comprising a noble gas tend to cause pits to form in the surface of the wafer. Most preferably, the atmosphere consists essentially of H₂. It should be noted that although atmospheres containing N₂ may be used, such atmospheres are less preferred because they tend to form nitrides on the surface which interfere with subsequent epitaxial deposition on the surface.

Traditionally, the epitaxial deposition protocols that remove a silicon oxide layer by heating a wafer in the presence of H₂ require the wafer to be heated to a high temperature (e.g., from about 1000 to about 1250° C.) and then baked at that temperature for a period of time (i.e., typically from about 10 to about 90 seconds). It has been discovered in accordance with this invention, however, that if the surface of the wafer is heated to about 1100° C. (and more preferably, about 1150° C.) in an atmosphere comprising H₂, the silicon oxide layer is removed without the subsequent bake step, thereby rendering the bake step unnecessary. Elimination of the bake step shortens the time required to prepare the wafer and, therefore, is commercially desirable.

In a preferred embodiment of this invention, the wafer surface is heated to remove the silicon oxide layer, and then the surface is exposed to an atmosphere containing silicon to deposit the epitaxial layer onto the surface. More preferably, the surface is exposed with the atmosphere containing silicon less than 30 seconds after the silicon oxide is removed, more preferably within about 20 seconds after the silicon oxide layer is removed, and most preferably within about 10 seconds after the silicon oxide layer is removed. In a particularly preferred embodiment, the wafer surface is heated to a temperature of at least about 1100° C. (more preferably, at least about 1150° C.), and then is exposed to an atmosphere containing silicon less than 30 seconds after the wafer surface reaches that temperature. More preferably, the surface is exposed to the atmosphere containing silicon within 20 seconds after the wafer surface reaches that temperature, and most preferably less within 10 seconds after the wafer surface reaches that temperature. Waiting to initiate silicon deposition for about 10 seconds after removal of the silicon oxide layer allows the temperature of the wafer to stabilize and become uniform.

During the removal of the silicon oxide layer, the wafer preferably is heated at a rate which does not cause slip. More specifically, if the wafer is heated too quickly, a thermal gradient will develop which will create an internal stress sufficient to cause different planes within the wafer to shift relative to each other (i.e., slip). Lightly doped wafers (e.g., a wafer doped with boron and having a resistivity of about 1 to about 10 ω-cm) have been found to be particularly susceptible to slip. To avoid this problem, the wafer preferably is heated from room temperature to the silicon oxide removal temperature at an average rate of about 20 to about 35° C./sec.

The epitaxial deposition preferably is carried out by chemical vapor deposition. Generally speaking, chemical vapor deposition involves exposing the surface of the wafer to an atmosphere comprising silicon in an epitaxial deposition reactor, e.g., an EPI CENTURA® reactor (Applied Materials, Santa Clara, Calif.). In a preferred embodiment of this invention, the surface of the wafer is exposed to an atmosphere comprising a volatile gas comprising silicon (e.g., SiCl₄, SiHCl₃, SiH₂Cl₂, SiH₃Cl, or SiH₄). The atmosphere also preferably contains a carrier gas (most preferably H₂). In one embodiment, the source of silicon during the epitaxial deposition is SiH₂Cl₂ or SiH₄. If SiH₂Cl₂ is used, the reactor pressure during deposition preferably is from about 500 to about 760 Torr. If, on the other hand, SiH₄ is used, the reactor pressure preferably is about 100 Torr. Most preferably, the source of silicon during the deposition is SiHCl₃. This tends to be much cheaper than other sources. In addition, an epitaxial deposition using SiHCl₃ may be conducted at atmospheric pressure. This is advantageous because no vacuum pump is required and the reactor chamber does not have to be as robust to prevent collapse. Moreover, fewer safety hazards are presented and the chance of air leaking into the reactor chamber is lessened.

During the epitaxial deposition, the temperature of the wafer surface preferably is maintained at a temperature sufficient to prevent the atmosphere comprising silicon from depositing polycrystalline silicon onto the surface. Generally, the temperature of the surface during this period preferably is at least about 900° C. More preferably, the temperature of the surface is maintained at from about 1050 to about 1150° C. Most preferably, the temperature of the surface is maintained at the silicon oxide removal temperature.

The rate of growth of the epitaxial deposition preferably is from about 3.5 to about 4.0 μm/min when the deposition is conducted under atmospheric pressure. This may be achieved, for example, by using an atmosphere consisting essentially of about 2.5 mole % SiHCl₃ and about 97.5 mole % H₂ at a temperature of about 1150° C.

If the intended use of the wafer requires that the epitaxial layer include a dopant, the atmosphere comprising silicon also preferably contains the dopant. For example, it is often preferable for the epitaxial layer to contain boron. Such a layer may be prepared by, for example, including B₂H₆ in the atmosphere during the deposition. The mole fraction of B₂H₆ in the atmosphere needed to obtain the desired properties (e.g., resistivity) will depend on several factors, such as the amount of boron out-diffusion from the particular substrate during the epitaxial deposition, the quantity of P-type dopants and N-type dopants that are present in the reactor and substrate as contaminants, and the reactor pressure and temperature. Applicants have successfully used an atmosphere containing about 0.03 ppm of B₂H₆ (i.e., about 0.03 mole of B₂H₆ per 1,000,000 moles of total gas) at a temperature of about 1125° C. and a pressure of about 1 atm. to obtain an epitaxial layer having a resistivity of about 10 ω-cm.

Once an epitaxial layer having the desired thickness has been formed, the atmosphere comprising silicon preferably is purged from the reaction chamber with a noble gas, H₂, or a combination thereof; and more preferably with H₂ alone. Afterward, the wafer preferably is cooled to a temperature of no greater than about 700° C. and then removed from the epitaxial deposition reactor.

Conventional epitaxial deposition protocols typically include a cleaning step following epitaxial deposition to remove byproducts formed during the epitaxial deposition. This step is used to prevent time-dependent haze, which results if such byproducts react with air. In addition, this step typically forms a silicon oxide layer on the epitaxial surface which tends to passivate (i.e., protect) the surface. Conventional post-epitaxial-deposition cleaning methods entail, for example, immersing the epitaxial surface in any of a number of cleaning solutions which are well-known to those of ordinary skill in the art. These solutions include, for example, piranha mixtures (i.e., mixtures of sulfuric acid and hydrogen peroxide), SC-1 mixtures (i.e., mixtures of H₂O, H₂O₂, and NH₄OH, also known as “RCA standard clean 1”), and SC-2 mixtures (i.e., mixtures of H₂O, H₂O₂, and HCl, also known as “RCA standard clean 2″). See, e.g., W. Kern, “The Evolution of Silicon Wafer Cleaning Technology,” J. Electrochem. Soc., Vol. 137, No. 6, 1887-92 (1990). Many such post-epitaxial-deposition cleaning steps require expensive wet cleaning equipment, large volumes of ultra-pure chemicals, additional wafer handling which often leads to additional yield losses.

In view of the above, it will be seen that the several objects of the invention are achieved. As various changes could be made in the above-described process without departing from the scope of the invention, it is intended that all matters contained in the above description be interpreted as illustrative and not in a limiting sense. In addition, when introducing elements of the present invention or the preferred embodiment(s) thereof, the articles “a,” “an,” “the” and “said” are intended to mean that there are one or more of the elements. The terms “comprising,” “including” and “having” are intended to be inclusive and mean that there may be additional elements other than the listed elements.

We claim:

1. A process for nucleating and growing oxygen precipitates in a silicon wafer having a front surface, a back surface, a central plane between the front and back surfaces, a front surface layer which comprises the region of the wafer between the front surface and a distance, D, measured from the front surface and toward the central plane, and a bulk layer which comprises the region of the wafer between the central plane and front surface layer, the wafer further comprising a non-uniform concentration of crystal lattice vacancies with the concentration of vacancies in the bulk layer being greater than the concentration of vacancies in the surface layer, the process comprising:
heating the wafer to a temperature, Tₙ, to form oxygen precipitate nuclei in the bulk layer wherein Tₙ is from about 750° C. to about 900° C.;
increasing the temperature from Tₙ to a temperature, T_{g}, to grow oxygen precipitates at the site of the nuclei wherein T_{g} is at least about 10° C. greater than Tₙ;
controlling the rate at which the temperature is increased from Tₙ to T_{g} to provide a population of oxygen precipitates which are stable at a processing temperature, Tₚ wherein Tₚ is greater than T_{g}; and,
cooling the wafer from T_{g} to a final temperature, T_{f}, wherein T_{f} is less than about 650° C. before the oxygen precipitates grow to a size of at least 30 nm.

2. A process for nucleating and growing oxygen precipitates in a silicon wafer having a front surface, a back surface, a central plane between the front and back surfaces, a front surface layer which comprises the region of the wafer between the front surface and a distance, D, measured from the front surface and toward the central plane, and a bulk layer which comprises the region of the wafer between the central plane and front surface layer, the wafer further comprising a non-uniform concentration of crystal lattice vacancies with the concentration of vacancies in the bulk layer being greater than the concentration of vacancies in the surface layer, the process comprising:
heat treating the wafer at a temperature, Tₙ, for a time period, tₙ of at least about 15 minutes to provide a diffusion length, Lₙ, wherein Tₙ is from about 750° C. to about 900° C.;
increasing the temperature from Tₙ to a temperature, T_{g}, over a time period tᵢ to provide a diffusion length Lᵢ, wherein T_{g} is at least about 10° C. greater than Tₙ;
optionally maintaining the wafer at the temperature, T_{g}, for a time period, t_{g} to provide a diffusion length L_{g};
cooling the wafer from T_{g} to a final temperature, T_{f}, over a time period t_{d} to provide a diffusion length, L_{d}, wherein T_{f} is less than about 650° C., such that the process provides a total diffusion length, Lₜ, determined by adding Lₙ, Lᵢ, L_{g} and L_{d} in quadrature, resulting in the formation of stabilized oxygen precipitates having an effective radius of from about 0.5 nm to about 30 nm in the bulk layer over a total cycle time, tₜ, which is equal to the sum of tₙ, tᵢ, t_{g} and t_{d}, and wherein the total cycle tₜ is at least about 20% less than a time period t_{n,i} required to provide a total diffusion length L_{n,i} equal to Lₜ by isothermally heat treating the wafer at the temperature Tₙ.

3. The process of claim 2 wherein Lₜ is at least about 0.19 μm.

4. The process of claim 2 wherein Lₜ is at least about 0.47 μm.

5. The process of claim 2 wherein Lₜ is at least about 0.95 μm.

6. The process of claim 2 wherein Lₜ is at least about 1.9 μm.

7. The process of claim 2 wherein the total cycle time, tₜ required to provide the total diffusion length, Lₜ, is at least about 30% less than a time period t_{n,i} required to provide a total diffusion length L_{n,i} equal to Lₜ by isothermally heat treating the wafer at the temperature Tₙ.

8. The process of claim 2 wherein the total cycle time, tₜ required to provide the total diffusion length, Lₜ, is at least about 50% less than a time period t_{n,i} required to provide a total diffusion length L_{n,i} equal to Lₜ by isothermally heat treating the wafer at the temperature Tₙ.

9. A process for the preparation of a silicon wafer having non-uniform concentration of stabilized oxygen precipitates, the wafer comprising a front surface, a back surface, a central plane between the front and back surfaces, a front surface layer which comprises the region of the wafer between the front surface and a distance, D, measured from the front surface and toward the central plane, and a bulk layer which comprises the region of the wafer between the central plane and front surface layer, wherein the process comprises:
subjecting the wafer to a heat treatment process to form crystal lattice vacancies in the front surface and bulk layers and controlling the cooling rate of the heat-treated wafer to produce a wafer having a vacancy concentration profile in which the concentration of vacancies in the bulk layer is greater than the concentration of vacancies in the surface layer; and,
subjecting the heat treated wafer, to a non-isothermal anneal to cause the formation of a denuded zone in the surface layer and the nucleation and growth of oxygen precipitates in the bulk layer, the anneal comprising (i) heating the wafer to a temperature, Tₙ, to form oxygen precipitate nuclei in the bulk layer wherein Tₙ is from about 750° C. to about 900° C. (ii) increasing the temperature from Tₙ to a temperature, T_{g}, to grow oxygen precipitates at the site of the nuclei wherein T_{g} is at least about 10° C. greater than Tₙ, (iii) controlling the rate at which the temperature is increased from Tₙ to T_{g} to provide a population of oxygen precipitates which are stable at a processing temperature, Tₚ, wherein Tₚ is greater than T_{g} and, (iv) cooling the wafer from T_{g} to a final temperature, T_{f}, wherein T_{f} is less than about 650° C. before the oxygen precipitates grow to a size of at least 30 nm.

10. The process of claim 9 wherein said heat-treatment to form crystal lattice vacancies comprises heating the wafers to a temperature in excess of about 1175° C. in a non-oxidizing atmosphere.

11. The process of claim 9 wherein said heat-treatment to form crystal lattice vacancies comprises heating the wafers to a temperature in excess of about 1200° C. in a non-oxidizing atmosphere.

12. The process of claim 9 wherein said heat-treatment to form crystal lattice vacancies comprises heating the wafers to a temperature in the range of about 1200° C. to about 1275° C. in a non-oxidizing atmosphere.

13. The process of claim 9 wherein said cooling rate is at least about 20° C. per second through the temperature range at which crystal lattice vacancies are relatively mobile in silicon.

14. The process of claim 9 wherein said cooling rate is at least about 50° C. per second through the temperature range at which crystal lattice vacancies are relatively mobile in silicon.

15. The process of claim 9 claim wherein said cooling rate is at least about 100° C. per second through the temperature range at which crystal lattice vacancies are relatively mobile in silicon.

16. The process of any one of claims 1, 2 or 9 further comprising subjecting wafer to a thermal process at a temperature of from about 1000 to about 1275 after cooling the wafer to a final temperature, T_{f}, wherein T_{f} is less than about 650° C.

17. The process of claim 16 wherein the thermal process is selected from a group consisting of an epitaxial deposition process, rapid thermal oxidation and rapid thermal nitridation.

18. The process of claim 17 wherein the thermal process is an epitaxial deposition process wherein an epitaxial layer is deposited on the wafer.

19. The process of any of claims 1, 2 or 9 wherein the wafer is maintained at T_{g} for a time period, tₙ, of at least about 30 minutes.

20. The process of any of claims 1, 2 or 9 wherein the wafer is maintained at T_{g} for a time period, tₙ, of at least about 60 minutes.

21. The process of any of claims 1, 2 or 9 wherein the temperature of the wafer is increase from Tₙ to T_{g} at a rate, ΔTᵢ, of from about 1° C./min to about 5° C./min.

22. The process of any of claims 1, 2 or 9 wherein the temperature of the wafer is increase from Tₙ to T_{g} at a rate, ΔTᵢ, of from about 2° C./min to about 4° C./min.

23. The process of any of claims 1, 2 or 9 wherein the temperature of the wafer is increase from Tₙ to T_{g} at a rate, ΔTᵢ, of from about 3° C./min to about 4° C./min.

24. The process of claim 23 wherein the wafer is maintained at T_{g} for a time period, tₙ, of at least about 30 minutes.

25. The process of claim 23 wherein the wafer is maintained at T_{g} for a time period, tₙ, of at least about 60 minutes.

26. The process of claim 23 wherein T_{g} is at least about 25° C. greater than Tₙ.

27. The process of claim 23 wherein T_{g} is at least about 50° C. greater than Tₙ.

28. The process of claim 23 wherein T_{g} is at least about 75° C. greater than Tₙ.

29. The process of claim 23 wherein T_{g} is at least about 100° C. greater than Tₙ.

30. The process of any of claims 1, 2 or 9 wherein Tₙ is from about 800° C. to about 850° C.

31. The process of any of claims 1, 2 or 9 wherein Tₙ is from about 800° C. to about 825° C.

32. The process of claim 31 wherein the wafer is maintained at T_{g} for a time period, tₙ, of at least about 30 minutes.

33. The process of claim 31 wherein the wafer is maintained at T_{g} for a time period, tₙ, of at least about 60 minutes.

34. The process of claim 33 wherein T_{g} is at least about 25° C. greater than Tₙ.

35. The process of claim 33 wherein T_{g} is at least about 50° C. greater than Tₙ.

36. The process of claim 33 wherein T_{g} is at least about 75° C. greater than Tₙ.

37. The process of claim 33 wherein T_{g} is at least about 100° C. greater than Tₙ.

38. The process of any of claims 1, 2 or 9 wherein T_{g} is from about 850° C. to about 1150° C.

39. The process of any of claims 1, 2 or 9 wherein T_{g} is from about 900° C. to about 1100° C.

40. The process of any of claims 1, 2 or 9 wherein T_{g} is from about 900° C. to about 1000° C.

41. A wafer sliced from a single crystal silicon ingot grown in accordance with the Czochralski method, the wafer comprising:
a front surface, a back surface, a central plane between the front and back surfaces, a front surface layer which comprises a region of the wafer between the front surface and a distance, D, measured from the front surface and toward the central plane, and a bulk layer which comprises a region of the wafer between the central plane and front surface layer;
a concentration of stabilized oxygen precipitates in the bulk layer; and
a denuded zone in the surface layer wherein D is at least about 5 microns but less than about 30 microns.

42. The wafer of claim 41 wherein D is greater than about 5 microns and less than about 25 microns.

43. The wafer of claim 41 wherein D is greater than about 5 microns and less than about 20 microns.

44. The wafer of claim 41 wherein D is greater than about 5 microns and less than about 15 microns.

45. The wafer of claim 41 wherein D is greater than about 5 microns and less than about 10 microns.

46. The wafer of claim 41 wherein D ranges from about 10 microns to about 25 microns.

47. The wafer of claim 41 wherein the bulk layer has an oxygen precipitate density of greater than about 1×10⁷ cm⁻³.

48. The wafer of claim 41 wherein the bulk layer has an oxygen precipitate density of greater than about 1×10⁸ cm⁻³.

49. The wafer of claim 41 wherein the bulk layer has an oxygen precipitate density of greater than about 1×10⁹ cm⁻³.

50. The wafer of claim 41 wherein the bulk layer has an oxygen precipitate density of greater than about 1×10¹⁰ cm³.

51. The wafer of claim 41 wherein the bulk layer has an oxygen precipitate density ranging from about 1×10⁸ cm⁻³ to about 1×10¹⁰ cm⁻³.

52. The wafer of claim 41 wherein the stabilized oxygen precipitates are stable at a temperature of at least about 1000° C.

53. The wafer of claim 41 wherein the stabilized oxygen precipitates are stable at a temperature of at least about 1100° C.

54. The wafer of claim 41 wherein the stabilized oxygen precipitates are stable at a temperature of at least about 1150° C.
